(19) United States
(12) Patent Application Publication
(10) Pub. No.: US 2006/0280218 A1
(43) Pub. Date: Dec. 14, 2006

(54) SURFACE-EMITTING TYPE SEMICONDUCTOR LASER

(75) Inventors: Tsuyoshi KANEKO, Suwa-shi (JP); Atsushi SATO, Suwa-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/279,323

(22) Filed: Apr. 11, 2006

(30) Foreign Application Priority Data
Jun. 14, 2005 (JP) 2005-173324

(51) Int. Cl. H01S 3/00; H01S 5/00; H01S 3/097; H01S 3/08

(52) U.S. Cl. 372/81; 372/50.11; 372/99; 372/38.05; 372/87

(57) ABSTRACT

A surface-emitting type semiconductor laser includes: an emission section including at least a lower mirror layer, an active layer and an upper mirror layer; a rectification section including at least a lower semiconductor layer and an upper semiconductor layer; a first conductive layer that electrically connects the upper mirror layer and the upper semiconductor layer; and a second conductive layer that electrically connects the lower mirror layer and the lower semiconductor layer, wherein the rectification section is electrically connected in parallel with the emission section by the first and second conductive layers and has a rectification action in a reverse direction with respect to the emission section, the first conductive layer includes a first land, and the second conductive layer includes a second land and a third land, and has a section extending from the second land and electrically connected to a first region of the lower semiconductor layer and a section extending from the third land and electrically connected to a second region of the lower semiconductor layer.

### BACKGROUND

The entire disclosure of Japanese Patent Application No. 2005-173324, filed Jun. 14, 2005 is expressly incorporated by reference herein.

1. Technical Field

The present invention relates to surface-emitting type semiconductor lasers.

2. Related Art

A surface-emitting type semiconductor laser has a smaller device volume compared to an ordinary edge-emitting type semiconductor laser, such that the electrostatic breakdown voltage of the device itself is low. For this reason, the device mav be damaged by static electricity caused by a machine or an operator in a mounting process. In particular, a surface-emitting laser has a certain tolerance to a forward bias voltage, but has a low tolerance to a reverse bias voltage, and the device may be destroyed when a reverse bias voltage is impressed. A variety of measures are usually implemented in a mounting process to remove static electricity, but these measures have limitations. For example, Japanese Laid-open Patent Application JP-A-2004-6548 describes an example of related art.

### SUMMARY

In accordance with an advantage of some aspects of the present invention, surface-emitting type semiconductor lasers that can effectively prevent electrostatic breakdown can be provided.

(1) In accordance with an embodiment of the invention, a surface-emitting type semiconductor laser includes: an emission section including at least a lower mirror layer, an active layer and an upper mirror layer; a rectification section including at least a lower semiconductor layer and an upper semiconductor layer; a first conductive layer that electrically connects the upper mirror layer and the upper semiconductor layer; and a second conductive layer that electrically connects the lower mirror layer and the lower semiconductor layer, wherein the rectification section is electrically connected in parallel with the emission section by the first and second conductive layers and has a rectification action in a reverse direction with respect to the emission section, the first conductive layer includes a first land, and the second conductive layer includes a second land and a third land, and has a section extending from the second land and electrically connected to a first region of the lower semiconductor layer and a section extending from the third land and electrically connected to a second region of the lower semiconductor layer.

According to the present embodiment, even when a reverse bias voltage is impressed to the emission section, a current flows to the rectification section that is connected in parallel with the emission section. such that the emission section would not be destroyed, and its tolerance against reverse bias voltages can be improved. Accordingly, electrostatic breakdown can be effectively prevented. Moreover, because the second conductive layer has a plurality of lands, appropriate ones of the lands can be freely selected as bonding regions, whereby the degree of freedom in design can be improved. Furthermore, the second conductive layer secures paths of electrical connection in multiple directions, which achieves a highly effective line disconnection preventing function.

It is noted that, in the present invention, the case of a layer B being provided above a specific layer A includes a case where the layer B is directly provided on the layer A, and a case where the layer B is provided over the layer A through another layer. This similarly applies to the following inventions.

(2) In the surface-emitting type semiconductor laser, the second conductive layer may have a line that electrically connects the second and third lands on a different side with respect to the rectification section, and the line of the second conductive layer may be bent in a direction to surround an inner area (preferably, a center area of the substrate) as viewed in a plan view.

According to the above, for example, an emission surface of the emission section can be provided at the center section, as viewed in a plan view.

(3) In the surface-emitting type semiconductor laser, the lower semiconductor layer may have a plane configuration that is bent in the same direction as the line of the second conductive layer.

By this, the layout design can be made compact.

(4) In the surface-emitting type semiconductor laser, an emission surface of the emission section may be provided in an inner area surrounded by the second conductive layer and the lower semiconductor layer.

By this, the layout design can be made compact.

(5) In the surface-emitting type semiconductor laser, the first land may be provided on the opposite side of the emission surface of the emission section through the upper semiconductor layer as a reference.

By this, an electric current securely flows to the rectification section when a reverse bias voltage is applied to the emission section. Consequently, the emission section can be prevented from being destroyed by the applied reverse bias voltage.

(6) In the surface-emitting type semiconductor laser, the upper semiconductor layer and the lower semiconductor layer may have a line-symmetrical plane configuration.

(7) In the surface-emitting type semiconductor laser, the second and third lands may be provided at positions line-symmetrical with each other.

(8) In the surface-emitting type semiconductor laser, the first region may be a region in an upper surface of one of end sections of the lower semiconductor layer, the second region may be a region in the upper surface of the other end section of the lower semiconductor layer, and the upper semiconductor layer may be provided above a center section between and separated from the first region and the second region of the lower semiconductor layer.

(9) In the surface-emitting type semiconductor laser, the first conductive layer may include a first electrode of a first conductivity type provided above the upper mirror layer, a second electrode of a second conductivity type provided above the upper semiconductor layer, and a first wiring layer that electrically connects the first and second electrodes.

(10) In the surface-emitting type semiconductor laser, the second conductive layer may include a third electrode of the second conductivity type provided above the lower mirror layer, a fourth electrode of the first conductivity type provided above the first region of the lower semiconductor layer, a fifth electrode of the first conductivity type provided above the second region of the lower semiconductor layer, and a second wiring layer that electrically connects the third, fourth and fifth electrodes.

(11) The surface-emitting type semiconductor laser may further include a resin layer, wherein the resin layer may be provided around the emission surface of the emission section and the lower semiconductor layer and as a base of the first land.

(12) The surface-emitting type semiconductor laser may further include a substrate that supports the emission section and the rectification section.

### BRIEF DESCRIPTION OF THE DRAWINGS

FIG. 1 is a plan view of a surface-emitting type semiconductor laser in accordance with an embodiment of the invention.

FIG. 2 is a cross-sectional view of the surface-emitting type semiconductor laser in accordance with the embodiment of the invention.

FIG. 3 is a circuit diagram of the surface-emitting type semiconductor laser in accordance with the present embodiment.

### DESCRIPTION OF EXEMPLARY EMBODIMENTS

A preferred embodiment of the invention is described below with reference to the accompanying drawings.

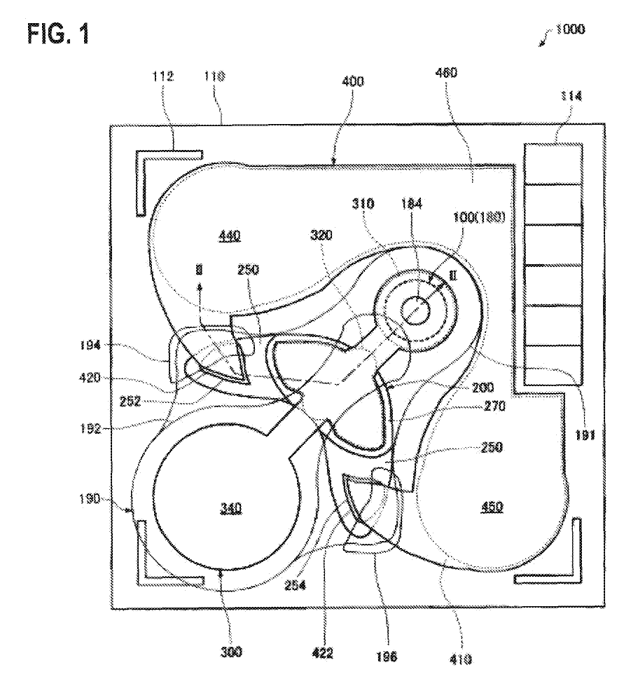

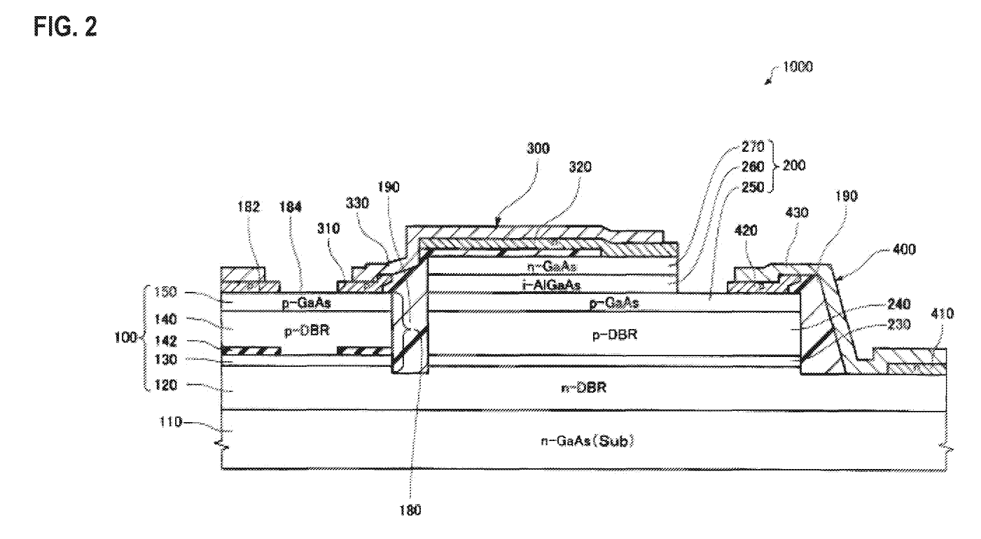

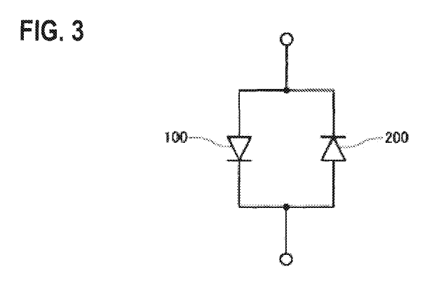

FIG. 1 is a plan view of a surface-emitting type semiconductor laser in accordance with an embodiment of the present invention. FIG. 2 is a cross-sectional view taken along a line II-II of FIG. 1. FIG. 3 is an equivalent circuit diagram of the surface-emitting type semiconductor laser.

The surface-emitting type semiconductor laser 1000 includes an emission section 100 and a rectification section 200.

The emission section 100 and the rectification section 200 are supported by a substrate 110. More specifically, the emission section 100 and the rectification section 200 are formed on one of surfaces of the substrate 110, and have a monolithic structure as a whole. The substrate 110 is a semiconductor substrate (for example, an n-type GaAs substrate). The substrate 110 is formed in the same conductivity type as that of a lower mirror layer 120 of the emission section 100. The substrate 110 has a plane configuration that may be, for example, a rectangular (square or oblong) shape, and may be provided with an alignment mark 112 and a marking region 114 at corner sections thereof, as viewed in a plan view.

A. Emission Section

The emission section 100 is a resonator (vertical resonator), and includes a columnar section 180 that contributes to light emission. In the example shown in FIG. 2, a convex protruded section in the cross-sectional configuration of the emission section 100 corresponds to the columnar section 180. The columnar section 180 has a side surface that may be orthogonal or positively tapered with respect to the substrate surface. He columnar section 180 has a plane configuration that may be in a circular shape, a rectangular (square or oblong) shape, or other polygonal shape. In the example shown in FIG. 1, a single columnar section 180 is formed on a single substrate 110. However, a plurality of columnar sections 180 may be formed on a single substrate 110. The center section of the upper surface 182 of the columnar section 180 defines an emission surface 184 for emission of a laser beam.

The emission section 100 includes a lower mirror layer 120, an active layer 130, an upper mirror layer 140 and a contact layer 150, which are successively provided in this order from the side of the substrate 110. The lower mirror layer 120 has a plane configuration that may be, for example, the same as the plane configuration of the substrate 110. In the example shown in FIG. 2, the contact layer 150 and the upper mirror layer 140 are formed in a first conductivity type (for example, p-type), and the lower mirror layer 120 is formed in a second conductivity type (for example, n-type). It is noted that the columnar section 180 refers to a semiconductor laminated body including at least the contact layer 150 and the upper mirror layer 140 (for example, including the contact layer 1O, the upper mirror layer 140, the active layer 130 and a portion of the lower mirror layer 120).

The lower mirror layer 120 may be, for example, a distributed reflection type multilayer mirror of 40 pairs of alternately laminated n-type Al_{0.9}Ga_{0.1}As layers and n-type Al_{0.15}Ga_{0.85}As layers. The active layer 130 may be composed of, for example, GaAs well layers and Al_{0.3}Ga_{0.7}As barrier layers in which the well layers include a quantum well structure composed of three layers. The upper mirror layer 140 may be, for example, a distributed reflection type multilayer mirror of 25 pairs of alternately laminated p-type Al_{0.9}Ga_{0.1}As layers and p-type Al_{0.15}Ga_{0.85}As layers. The contact layer 150 at the topmost surface may be composed of, for example, a p-type GaAs layer. It is noted that the composition of each of the layers and the number of the layers forming these layers are not limited to the above.

The upper mirror layer 140 is formed to be p-type by doping C, Zn, Mg or the like, and the lower mirror layer 120 is formed to be n-type by doping Si, Se or the like. Accordingly, the upper mirror layer 140, the active layer 130 in which no impurity is doped, and the lower mirror layer 120 form a pin diode.

A current constricting layer 142 composed of aluminum oxide as the main component is formed in a region near the active layer 130 among the layers forming the upper mirror layer 140. The current constricting layer 142 may be formed, for example, in a ring shape. In other words, the current constricting layer 142 has a cross section defining concentric circles when cut in a plane parallel with the emission surface 184.

B. Rectification Section

The rectification section 200 is electrically connected in parallel with the emission section 100 by first and second conductive layers 300 and 400 to be described below, and has a rectification action in a reverse direction with respect to the emission section 100 (see FIG. 3). The rectification section 200 is, for example, a junction diode. The rectification section 200 is provided in a region different from the columnar section 180 described above, as viewed in a plan view.

The rectification section 200 includes a lower semiconductor layer 250, a capacitance reducing layer 260 and an upper semiconductor layer 270. In the example shown in FIG. 2, the lower mirror layer 120, a semiconductor layer 230 composed of the same composition as that of the active layer 130, and a semiconductor layer 240 composed of the same composition as that of the upper mirror layer 140 are provided in this order from the side of the substrate 110 between the substrate 110 and the lower semiconductor layer 250. When the semiconductor layer 240 is formed in the same conductivity type (for example, p-type) as that of the lower semiconductor layer 250, and contributes to operations of a pn junction diode, the semiconductor layer 240 also forms a part of the rectification section 200. It is noted that a dielectric layer (not shown) that is formed by the same process conducted for forming the current constricting layer 142 described above may be provided in the semiconductor layer 240 in a region adjacent to the lower semiconductor layer 230.

The upper semiconductor layer 270 has a plane configuration that is the same as the plane configuration of the capacitance reducing layer 260. Also, the plane configuration of the upper semiconductor layer 270 is smaller than (for example, about 1/3 of) the plane configuration of the lower semiconductor layer 250. In other words, a portion of the upper surface of the lower semiconductor layer 250 is exposed through the upper semiconductor layer 270 and the capacitance reducing layer 260. By this, at least a part of the exposed region can be used as an electrical connection region (first and second regions 252 and 254).

The plane configuration of the upper semiconductor layer 270 may be made as large as possible. By this, the interface area of the pn junction (pin junction) can be made larger, and the resistance of the rectification section 200 against a forward bias can be made smaller.

In the example shown in FIG. 1, the first and second regions 252 and 254 defining electrical connection regions in the lower semiconductor layer 250 are separated from each other. The first and second regions 252 and 254 generally overlap regions for electrodes (fourth and fifth electrodes 420 and 422 to be described below) to be provided on the lower semiconductor layer 250. In the example shown in FIG. 1, the first region 252 is a region of the upper surface at one of end sections of the lower semiconductor layer 250 as viewed in a plan view, and the second region 254 is a region of the upper surface at the other end section of the lower semiconductor layer 250 as views in a plan view. Also, the upper semiconductor layer 270 and the capacitance reducing layer 260 are provided in a center section (which may be referred to as a curved section in FIG. 1) of the upper surface of the lower semiconductor layer 250. In other words, the upper semiconductor layer 270 and the capacitance reducing layer 260 are provided respectively at positions above and separated from the first and second regions 252 and 254. By this, diffusion of metals of mutually different conductive types can be prevented.

As shown in FIG. 1, each of the lower semiconductor layer 250 and the upper semiconductor layer 270 has a line-symmetrical plane configuration. Their reference lines may coincide with each other and can be defined by, for example, a diagonal line of the substrate 110 (or a line extending along a direction in which the first conductive layer 300 extends, as described below). Also, the plane configuration of the lower semiconductor layer 250 has a bent section that bends in a predetermined direction, such as, a generally L-shape, a generally U-shape, or a generally V-shape. In the example shown in FIG. 1, the plane configuration of the lower semiconductor layer 250 is bent such that its end sections extend in directions that move away from the columnar section 180 (in other words, in directions that surround the first land 340). Also, the plane configuration of the lower semiconductor layer 250 can be said to bend in the same direction as the bent direction of a line 460 of a second conductive layer 400 to be described below. By this, the layout design can be made compact.

In the example shown in FIG. 2, the lower semiconductor layer 250 is positioned at the same height as that of the contact layer 150 of the emission section 100. Also, the capacitance reducing layer 260 and the upper semiconductor layer 270 are provided at a level higher than the emission section 100.

The lower semiconductor layer 250 is formed to be in a first conductivity type (for example, p-type), and may be formed in the same composition as that of, for example, the contact layer 150. Also, the upper semiconductor layer 270 is formed to be in a second conductivity type (for example, n-type), and may be formed from, for example, a GaAs layer. It is noted that the tipper semiconductor layer 270 is not limited to any particular material as long as it is in a conductivity type different from that of the lower semiconductor layer 250.

The capacitance reducing layer 260 is provided between the upper semiconductor layer 270 and the (for example, p-type) lower semiconductor layer 250. By this, the capacitance of the junction diode can be lowered, and the surface-emitting type semiconductor laser can be driven at higher speeds.

The capacitance reducing layer 260 can be formed from a semiconductor material. For example, the capacitance reducing layer 260 may be an intrinsic semiconductor layer (including a layer whose impurity concentration is at a level that can almost be ignored). In this case, the rectification section 200 forms a pin diode. Alternatively, the capacitance reducing layer 260 may be formed in the same conductivity type as that of the lower semiconductor layer 250 (or the upper semiconductor layer 270), and may have an impurity concentration lower (for example, an impurity concentration lower by one digit or more) than that of the lower semiconductor layer 250.

The capacitance reducing layer 260 can be formed from, for example, an AlGaAs layer. If the capacitance reducing layer 260 is formed from a material different from that of the lower semiconductor layer 250 that serves as a base layer (for example, a Ga s layer), a selection ratio in etching can be obtained. In other words, by etching, the upper surface of the lower semiconductor layer 250 can be readily exposed.

C. Conductive Layer

The emission section 100 and the rectification section 200 are electrically connected to each other by first and second conductive layers 300 and 400. More specifically, the first conductive layer 300 electrically connects the (p-type, for example) upper mirror layer 150 and the (n-type, for example) upper semiconductor layer 270, and the second conductive layer 400 electrically connects the (n-type, for example) lower mirror layer 120 and the (p-type, for example) lower semiconductor layer 250. The rectification section 200 is electrically connected in parallel with the emission section 100 by the first and second conductive layers 300 and 400.

The first conductive layer 300 includes a first electrode 310 of a first conductivity type (for example, p-type) provided above the upper mirror layer 140 (more specifically, on the contact layer 150), a second electrode 320 of a second conductivity type (for example, n-type) provided above the upper semiconductor layer 270, and a first wiring layer 330 that electrically connects the first and second electrodes 310 and 320.

As the first and second electrodes 310 and 320, at least one layer of Au, Pt, Ti, Zn, Cr, Ni, or an alloy of at least two of the aforementioned metals can be selected as a material suitable to be p-type, and at least one layer of Au, Ge, Ni, In, W, Cr or an alloy of at least two of the aforementioned metals can be selected as a material suitable to be n-type. Also, the first wiring layer 330 may be formed from, for example, a gold layer.

The first electrode 310 is electrically connected to an upper surface 182 of the columnar section 180. For example, the first electrode 310 is electrically connected to the contact layer 150 at an end section of the upper surface 182 of the columnar section 180 (in other words, at a region avoiding the emission surface 184). In the example shown in FIG. 1, the first electrode 310 has a plane configuration in a ring shape that surrounds the emission surface 184 of the emission section 100. By this, the current flowing in the columnar section 180 can be made uniform. Also, the second electrode 320 may have a plane configuration that is similar to the plane configuration of the upper semiconductor layer 270.

The first conductive layer 300 includes a first land 340. It is noted here that a land means a region for external electrical connection, and may be a region that can be used as a bonding region to bond a conductive member such as a wire and a bump. Accordingly, the plane configuration of the first land 340 may be appropriately decided according to the width of a wire or a bump, and may have in many cases a two-dimensionally expanding shape, such as, a circular shape or a rectangular shape. In other words, the first land 340 may often have a width greater than the width of a so-called line that is connected to the first land 340. For example, the first land 340 may have an area defined by a virtual circle (not shown) of a maximum radius that can be drawn in the first conductive layer 300. It is noted that the first land 340 may be composed of the first wiring layer 330 alone, or may be composed of the first wiring layer 330 and a base layer (for example, a layer composed of the same material as that of the first electrode 310). The base layer can be formed by, for example, the same process conducted for forming the first electrode 310. By providing the base layer, adhesion of the first land 340 can be improved.

As shown in FIG. 1, the first land 340 is provided on the opposite side of the emission surface 184 of the emission section 100 with the upper semiconductor layer 270 as being a reference. In other words, when viewed in a plan view, the emission surface 184 of the emission section 100, the rectification section 200 and the first land 340 are sequentially provided. They may be provided on a common virtual linear line (not shown) (for example, on a diagonal line of the substrate). By this, the columnar section 180 and the first land 340 can be electrically connected to each other in the shortest distance. Also, because the rectification section 200 is provided between the columnar section 180 and the first land 340, an electrical current can securely flow to the rectification section 200 when a reverse bias voltage is applied to the emission section 100. For this reason, the emission section 100 can be securely prevented from being destroyed by application of a reverse bias voltage.

(C-2) The second conductive layer 400 includes a third electrode 410 of a second conductivity type (for example, n-type) provided on the lower mirror layer 120, a fourth electrode 420 of a first conductivity type (for example, p-type) provided on the first region 252 of the lower semiconductor layer 250, a fifth electrode 422 of the first conductivity type (for example, n-type) provided on the second region 254 of the lower semiconductor layer 250, and a second wiring layer 430 that electrically connects the third, fourth and fifth electrodes 410, 420 and 422. The details described above can be applied to the materials of these layers and wiring.

The second conductive layer 400 includes second and third lands 440 and 450. The second and third lands 440 and 450 mean regions for external electrical connection, as described above, and may each have a plane configuration that is, for example, a circular shape or a rectangular shape. In other words, the second and third lands 440 and 450 may have a width greater than the width of a so-called line 460 that mutually connects them. For example, each of the second and third lands 440 and 450 may have a region defined bv a virtual circle (not shown) of a maximum radius that can be drawn in the second conductive layer 400. Also, the second and third lands 440 and 450 are provided at mutually line-symmetrical positions. Their reference line may be, for example, a diagonal line of the substrate 110 (or a line extending along a direction in which the first conductive layer 300 extends). Also, the second and third lands 440 and 450 are provided adjacent to opposed corner sections of the substrate 110, respectively. It is noted that the second and third lands 440 and 450 may be formed from the second wiring layer 430 alone, or may be formed from the second wiring layer 430 and the third electrode 410. By providing the third electrode 410, adhesion of the second and third lands 440 and 450 can be improved.

In effect, either the second land 440 or the third land 450 may be used as an external electrical connection section. By this, one of the lands can be freely selected as a bonding region, whereby the degree of freedom in design can be improved. For example, when an external electrical connection is made with wire bonding, one of the second and third lands 440 and 450 which is located at the shortest distance can be used as a bonding region. By this, the wire length or the loop height can be made to the minimum. This can be made more effective when the second and third lands 440 and 450 are provided at mutually line-symmetrical positions, as shown in FIG. 1.

The second conductive layer 400 extends from the second land 440 and is electrically connected to the first region 252 of the lower semiconductor layer 250, and extends from the third land 450 and is electrically connected to the second region 254 of the lower semiconductor layer 250. In other words, the second conductive layer 400 secures paths of electrical connection in multiple directions, which provides a highly effective line disconnection preventing function. Also, due to the multiple electrical current paths, the effect of protection against static electricity that is a transient phenomenon can be increased compared to the case of a single electrical current path.

The second conductive layer 400 has a line 460 that electrically connects the second and third lands 440 and 450. In the example shown in FIG. 2, the line 460 electrically connects the second and third lands 440 and 450 on a side different from the rectification section 200. Furthermore, the line 460 is bent in a direction that surrounds an inner area (of the substrate 110) (for example, a center area of the substrate 110) as viewed in a plan view. For example, the line 460 may be in a generally L-shape along two adjacent sides of the substrate 110 as viewed in a plan view. The rim of the line 460 on the center side of the substrate 110 may be curved in a concave shape. Also, the emission surface 184 (the columnar section 180) of the emission section 100 is provided on the inner side surrounded by the second conductive layer 400 and the lower semiconductor layer 250. Also, the emission surface 184 (the columnar section 180) of the emission section 100 and the upper semiconductor layer 270 are provided on the inner side (in the center section of the substrate 110) surrounded by the first land 330 and the second conductive layer 400.

D. Resin Layer

A resin layer 190 is provided over the substrate 110 (over the lower mirror layer 120). In the example shown in FIG. 1, the resin layer 190 is provided at least around the emission surface 184 (the columnar section 180) of the emission section 100 and the lower semiconductor layer 250 (the rectification section 200), and as a base layer of the first land 340. The resin layer 190 may be formed from, for example, polyimide resin, fluororesin, acrylic resin, or epoxy resin. Also, the resin layer 190 may be provided in a plurality of layers and/or in a plurality of regions.

A first resin layer 191 is provided around the columnar section 180 and the rectification section 200, and is further provided as a base layer of the first land 340. The first resin layer 191 may be patterned by a common process.

A second resin layer 192 is formed as a base layer of the first wiring layer 330, and is provided extending from the columnar section 180 over the upper semiconductor layer 270 and reaching the first land 340. Further, second resin layers 194 and 196 are provided extending from the lower semiconductor layer 250 onto the lower mirror layer 120 at a lower position. In any of the cases, these resin layers can form smooth sloped surfaces, which would cancel step differences formed in the device fabrication and enhance the line disconnection preventing effect. It is noted that the second resin layers 192, 194 and 196 can be patterned in the same step after the first resin layer 191 has been formed. Also, the resin layer 190 described above can be formed before the steps of forming the first and second conductive layers 300 and 400.

E. Method for Manufacturing Surface-emitting Type Semiconductor Laser

Next, a method for manufacturing the surface-emitting type semiconductor laser 1000 described above is described in outline with reference to FIG. 1 and FIG. 2 that are as-built drawings.

First, a substrate 110 is prepared, and a semiconductor multilayer film composed of a plurality of layers is formed on the substrate 110 by epitaxial growth while varying the composition. The semiconductor multilayer film includes a layer for forming a lower mirror layer 120, a layer for forming an active layer 130 and a semiconductor layer 230, a layer for forming an upper mirror layer 140 and a semiconductor layer 240, a layer for forming a contact layer 150 and a lower semiconductor layer 250, a layer for forming a capacitance reducing layer 260, and a layer for forming an upper semiconductor layer 270. It is noted that an AlAs layer or an AlGaAs layer with Al composition being 0.95 or greater may be formed for forming a current constricting layer 142 if necessary.

A metal-organic vapor phase deposition (MOVPE: Metal-Organic Vapor Phase Epitaxy) method, a MBE (Molecular Beam Epitaxy) method or a LPE (Liquid Phase Epitaxy) method can be used as a method for the epitaxial growth.

Then, the semiconductor multilayer film (not shown) is patterned (more specifically, etched) in a plurality of divided steps such that a specified plane configuration can be obtained in each of the layers described above. Patterning may be typically conducted through exposing and developing a resist in a specified plane configuration, and etching in an opening area in the resist. In this manner, each of the layers can be patterned in a specified configuration according to the plane configuration of the resist (see FIG. 2).

Next, a current constricting layer 142 is formed by oxidation in a water vapor atmosphere at about 400° C., for example. In the surface-emitting type semiconductor laser 1000, an electric current flows, when it is driven, only in a portion where the current constricting layer 142 is not formed. Therefore, the current density can be controlled consequentially by controlling the forming region of the current constricting layer 142.

Next, a resin layer 190 is formed at specified areas by patterning. The resin layer 190 can be formed by a known technique such as a dipping method, a spray coat method, a droplet jetting method (for example, an ink jet method), an etching method or the like. Then, first through fifth electrodes 310 through 422, and first and second wiring layers 330 and 430 are formed by, for example, a lift-off method or an etching method, thereby forming first and second conductive layers 300 and 400. Also, depending on the necessity, a protection layer (not shown) (for example, a silicon oxide layer or a silicon nitride layer) may be formed after the steps of patterning the semiconductor multilayer film. The protection layer may be formed as a base layer as the resin layer 190.

In this manner, the surface-emitting type semiconductor laser 1000 shown in FIG. 2 can be obtained.

F. Others

In the surface-emitting type semiconductor laser 1000 described above, a bias is impressed through the first land 340 and the second land 440 (or the third land 450). In the emission section 100, when a forward bias is applied to the pin diode by the first and third electrodes 310 and 410, recombinations of electrons and holes occur in the active layer 130, thereby causing emission of light due to the recombinations. Stimulated emission occurs when the generated light reciprocates between the lower mirror layer 120 and the upper mirror layer 140, whereby the light intensity is amplified. When the optical gain exceeds the optical loss, laser oscillation occurs, and a laser beam is emitted from the emission surface 184 in a direction orthogonal to the substrate 110.

It is noted here that, in accordance with the present embodiment, the rectification section 200 is electrically connected in parallel with the emission section 100 by the first and second conductive layers 300 and 400, and has a rectification action in a reverse direction with respect to the emission section 100. For this reason, even when a reverse bias is impressed to the emission section 100, an electrical current flows to the rectification section 200 that is electrically connected in parallel with the emission section 100. Therefore the emission section 100 would not be destroyed, and its tolerance against a reverse bias can be improved. Accordingly, highly reliable surface-emitting type semiconductor lasers that can effectively prevent electrostatic destruction, and excel in handing can be provided.

On the other hand, when the emission section 100 is driven, a forward bias is impressed to the emission section 100. In this instance, because an electric current is circulated only in the emission section 100, the breakdown voltage of the junction diode of the rectification section 200 can be made greater than the drive voltage of the emission section 100. By so doing, even when a forward bias is impressed at the time of driving the emission section 100, no (or almost no) reverse current flows in the rectification section 200, such that a normal light emission action is performed solely by the emission section 100.

It is noted that the breakdown voltage value of the rectification section 200 can be appropriately controlled by adjusting the composition or impurity concentration of the lower semiconductor layer 250 and the upper semiconductor layer 270. For example, by lowering the impurity concentration of the lower semiconductor layer 250 and the upper semiconductor layer 270, the breakdown voltage of the rectification section 200 can be increased. In the case of the present embodiment, the lower semiconductor layer 250 and the upper semiconductor layer 270 are both formed independently of the semiconductor layers that contribute to light emission actions of the emission section 100. In particular, the upper semiconductor layer 270 can be formed without relying on the structure of the emission section 100, such that its composition and impurity concentration can be freely adjusted. Therefore the rectification section 200 with more ideal characteristics can be readily formed, and effective prevention of electrostatic destruction and more stable emission action can be realized. Also, in accordance with the present embodiment, the key elements, such as, the emission surface 184 (the columnar section 180) of the emission section 100 and the rectification section 200, are gathered in a center area of the substrate 110, such that damage to the element section by, for example, a pyramid collet or the like can be prevented, and their handling in the mounting process is very easy. Moreover, in accordance with the present embodiment, as described above, the layout design can be optimized (whereby the layout design can be made compact, the reliability and the degree of freedom in design can be improved, and so forth).

It is noted that, in the present embodiment, the p-type and n-type characteristics of each of the semiconductor layers in the above described embodiment can be interchanged. The above example is described as using AlGaAs type material, but other materials, such as, for example, GaInP type, ZnSSe type, InGaN type, AlGaN type, InGaAs type, GaInNAs type, and GaAsSb type semiconductor materials can also be used depending on the oscillation wavelength to be generated.

Also, the substrate 110 may be omitted in the embodiment described above. More specifically, after the emission section 100 and the rectification section 200 are formed on the substrate 110, a surface-emitting type semiconductor laser may be manufactured bv using a method of finally peeling off the substrate 110 (i.e., an epitaxial lift-off method).

The present invention is not limited to the embodiment described above, and many modifications can be made. For example, the present invention may include compositions that are substantially the same as the compositions described in the embodiment (for example, a composition with the same function, method and result, or a composition with the same objects and result). Also, the present invention includes compositions in which portions not essential in the compositions described in the embodiment are replaced with others. Also, the present invention includes compositions that can achieve the same functions and effects or achieve the same objects of those of the compositions described in the embodiment. Furthermore, the present invention includes compositions that include publicly known technology added to the compositions described in the embodiment.

What is claimed is:

1. A surface-emitting type semiconductor laser comprising:
an emission section including at least a lower mirror layer, an active layer and an upper mirror layer;
a rectification section including at least a lower semiconductor layer and an upper semiconductor layer;
a first conductive layer that electrically connects the upper mirror layer and the upper semiconductor layer; and
a second conductive layer that electrically connects the lower mirror layer and the lower semiconductor layer, wherein
the rectification section is electrically connected in parallel with the emission section by the first and second conductive layers and has a rectification action in a reverse direction with respect to the emission section,
the first conductive layer includes a first land, and
the second conductive layer includes a second land and a third land, and has a section extending from the second land and electrically connected to a first region of the lower semiconductor layer and a section extending from the third land and electrically connected to a second region of the lower semiconductor layer.

2. A surface-emitting type semiconductor laser according to claim 1, wherein the second conductive layer has a line that electrically connects the second and third lands on a different side with respect to the rectification section, and the line of the second conductive layer is bent in an orientation to surround an inner area in a plan view.

3. A surface-emitting type semiconductor laser according to claim 2, wherein the lower semiconductor layer has a plane configuration that is bent in the same orientation as the line of the second conductive layer.

4. A surface-emitting type semiconductor laser according to claim 1, wherein an emission surface of the emission section is provided in an inner area surrounded by the second conductive layer and the lower semiconductor layer.

5. A surface-emitting type semiconductor laser according to claim 1, wherein the first land is provided on an opposite side of the emission surface of the emission section with the upper semiconductor layer as a reference.

6. A surface-emitting type semiconductor laser according to claim 1, wherein each of the upper semiconductor layer and the lower semiconductor layer has a line-symmetrical plane configuration.

7. A surface-emitting type semiconductor laser according to claim 1, wherein the second and third lands are provided at positions line-symmetrical with each other.

8. A surface-emitting type semiconductor laser according to claim 1, wherein the first region is a region in an upper surface of one of end sections of the lower semiconductor layer, the second region is a region in the upper surface of the other end section of the lower semiconductor layer, and the upper semiconductor layer is provided above a center section between and separated from the first region and the second region of the lower semiconductor layer.

9. A surface-emitting type semiconductor laser according to claim 1, wherein the first conductive layer includes a first electrode of a first conductivity type provided above the upper mirror layer, a second electrode of a second conductivity type provided above the upper semiconductor layer, and a first wiring layer that electrically connects the first and second electrodes.

10. A surface-emitting type semiconductor laser according to claim 1, wherein the second conductive layer includes a third electrode of the second conductivity type provided above the lower mirror layer, a fourth electrode of the first conductivity type provided above the first region of the lower semiconductor layer, a fifth electrode of the first conductivity type provided above the second region of the lower semiconductor layer, and a second wiring layer that electrically connects the third, fourth and fifth electrodes.

11. A surface-emitting type semiconductor laser according to claim 1, further comprising a resin layer, wherein the resin layer is provided around the emission surface of the emission section and the lower semiconductor layer and as a base of the first land.

12. A surface-emitting type semiconductor laser according to claim 1, further comprising a substrate that supports the emission section and the rectification section.

13. A surface-emitting type semiconductor laser according to claim 1, further comprising a marking region adjacent to the line.

14. A surface-emitting type semiconductor laser according to claim 1, further comprising alignment marks adjacent to the first land, the second land and the third land.

15. A surface-emitting type semiconductor laser according to claim 14, further comprising a resin layer under the first land, wherein a part of resin layer is disposed on a part of the alignment mark.

16. A surface-emitting type semiconductor laser according to claim 10, wherein the second land and the third land is disposed on the third electrode.
